(19) United States
(12) Patent Application Publication
(10) Pub. No.: US 2007/0105340 A1
(43) Pub. Date: May 10, 2007

(54) Interlayer bond to a substrate which, at least in regions on a surface, is provided with a coating of a metal, a method for production thereof and use

(76) Inventors: Ulrich Todt, Moritzburg (DE); Olaf Ruediger Hild, Radebeul (DE); Frank Loeffler, Dresden (DE); Claus Luber, Dresden (DE); Thomas Sonnabend, Dresden (DE)

Correspondence Address: JACOBSON HOLMAN PLLC, 400 SEVENTH STREET N.W., SUITE 600, WASHINGTON, DC, 20004, US

(21) Appl. No.: 11/543,995

(22) Filed: Oct. 6, 2006

(30) Foreign Application Priority Data
Oct. 7, 2005 (DE) 10 2005 048 774.2

(51) Int. Cl. H01L 21/30; H01L 23/58

(52) U.S. Cl. 438/455; 257/629

(57) ABSTRACT

The invention relates to substrates which, at least in regions on a surface, are provided with a coating of a metal, a method for producing such substrates and the use thereof. It is thereby the object of the invention to improve the adhesion of a coating of a metal on electrically non-conducting substrates or layers disposed on substrates. However, further properties can also be improved. For this purpose, the substrates are provided on their surface or on an electrically non-conducting layer with an intermediate layer which improves the adhesion, the coating with the metal being formed in turn on said intermediate layer. On the intermediate layer, a further layer comprising a semiconducting material or material mixture is formed at least in regions. The intermediate layer is formed from a metal oxide and/or a sulphide, the metal oxide and/or sulphide for the further layer which comprises a semiconducting material or material mixture having an injection barrier of less than equals 0.6 eV.

The invention relates to interlayer bonds to substrates which, at least in regions on a surface, are provided with a coating of a metal, a production method and use as field effect transistor.

The substrates are formed at least in regions from an electrically non-conducting material or an electrically non-conducting layer is formed on the substrate. The electrical conductivity of a semiconducting layer is greater than that of an electrically non-conducting substrate or of such a layer and the electrical conductivity of an electrically conducting layer or coating is in turn greater than that of a semiconducting layer. The electrical conductivity should thereby be less approx. by the factor one thousand than the electrical conductivity of the metallic coating.

A coating of a metal is then intended to be applied on the surface of the substrate for the most varied of applications, said coating being able to form a structure which represents for example an electrical strip conductor or similar.

Problems frequently occur thereby with the adhesion of such a metallic coating. This applies in particular to noble metals, such as e.g. gold on silicon, an oxide layer being formed on the latter.

In addition, contamination can result due to diffusion effects.

In particular when an interlayer bond of this type is intended to be used as field effect transistor, the formation of injection barriers in addition has a disadvantageous effect which, as a result of a high work function, restricts a desired emergence of charge carriers into adjacent further layers for increasing the charge carrier density in the current-conducting channel.

It is thus known to form a chromium layer which improves adhesion on a silicon substrate on which a silicon oxide layer is formed, a gold layer being able to be formed in turn on said chromium layer. In this case however, an increased barrier effect occurs, in addition the use of chromium is disadvantageous because of its possible toxic effect.

It is thus proposed in DE 43 22 512 A1 to deposit a metallic intermediate layer, in particular a chromium layer, on a polymer substrate in a vacuum in a very specific procedure. First pure chromium, then, in an intermediate phase, chromium together with an electrically readily conducting metal such as copper, aluminium, gold or silver and then, finally, only the readily electrically conducting metal alone is thereby intended to be deposited.

The high reactivity of chromium with oxygen thereby has an effect and must be taken into account.

It is therefore the object of the invention to improve the adhesion of a coating of a metal on electrically non-conducting substrates or on such a layer which is formed on the substrate.

It is a further object to produce a layer bond which can be used as an electronic component, in particular as a transistor, in which in particular current-conducting layers can be used which only have a low charge carrier density.

These objects are achieved according to the invention with an interlayer bond which has the features of claim 1. The bond can be produced by a method according to claim 14. Claim 16 describes an advantageous use. Claim 17 describes a field effect transistor which has an interlayer bond according to the invention.

Advantageous embodiments and developments can be achieved by the features described in the subordinate claims.

The interlayer bond according to the invention has a substrate, the substrate comprising electrically non-conducting material or the substrate provided with such a layer being provided, over its entire surface or only on surface regions which are subsequently provided with a coating of a metal, with an intermediate layer of a metal oxide and/or of a sulphide which improves the adhesion. On the intermediate layer, a further layer comprising a semiconducting material or material mixture is formed at least in regions. According to the invention, the metal oxide and/or sulphide for the further layer which comprises a semiconducting material or material mixture has an injection barrier of less than equals 0.6 eV (electron volt).

The intermediate layer is formed particularly preferably from an electrically conducting or semiconducting metal oxide.

For example indium-tin oxide, tin oxide, zinc oxide, zinc-aluminium oxide, antimony oxide or cadmium stannates are suitable for this purpose.

Suitable sulphides are for example cadmium sulphide and zinc sulphide.

The intermediate layer can thereby be formed from a metal oxide or a sulphide. However a mixture of a metal oxide and a sulphide can also be used for forming an intermediate layer.

The electrical conductivity can also be achieved or improved however by doping of the metal oxide with at least one element.

There can be used as electrically conducting coating, gold, silver, aluminium, platinum, palladium, nickel, copper, zinc, iridium or an alloy with at least one of these metals.

An electrically non-conducting layer on the surface can be silicon dioxide which is formed in turn on a substrate which can comprise pure or doped silicon. Instead of the silicon dioxide, a different electrically non-conducting layer can however also be present or be formed. Hence a polymer layer can be applied.

An electrically non-conducting layer on which an intermediate layer and then a coating is intended to be formed need not necessarily be disposed directly on the surface of a substrate. This can concern an electrically non-conducting layer which is disposed in a layer system so that at least one other layer can be present apart from the coating under this layer or also above it.

The intermediate layer which improves adhesion should have a thickness of at least 0.1, preferably up to 50 nm. This layer thickness can however also be significantly larger.

As a result, an undesired diffusion of the various substances (atoms, ions) of the layers or from the substrate into a layer or the coating can be avoided, at least however significantly impeded.

In addition, conductivity barriers can be minimised and optimal adaptation to the metal can be achieved for the coating. This is advantageous in particular in the field of use of small electrical voltages, in particular in the range between −5 and 5 V.

With the intermediate layer, also structural irregularities on the surface of the substrate can be compensated for and smoothness (reduction of the surface roughness) and also improved layer growth for the coating with metal can be achieved.

Both the formation of the intermediate layer and also that of the coating can be effected by means of conventional vacuum coating methods. Thus thermal evaporation of a metal oxide and subsequently of the metal can be implemented. However, also a CVD or PVD method can be used for formation of the intermediate layer and/or of the coating.

Structuring of the coating and/or intermediate layer formed on the surface of a substrate is likewise possible. This can be implemented at the same time as the formation of the respective layer but also subsequent thereto. For this purpose, likewise technologies which are known per se, such as e.g. etching processes, lift-off or direct masking (shadow masking) can be used.

An interlayer bond formed according to the invention can be developed in that a further layer comprising a semiconducting material or material mixture is applied. Such a layer can also cover the coating of the metal. There are suitable in particular organic semiconducting materials, such as e.g. pentacene, metal-containing and metal-free phthalocyanines, oligomers and polymers (oligo- and polythiophenes), polyarylamine, tetracene, oligothiophenes, polythiophenes, metal-containing and metal-free naphthalocyanines, metal-containing and metal-free porphyrins, perylene and derivatives of the mentioned materials.

However the further layer can also be semiconducting by means of at least one doped element or chemical compound.

For example, the metallic coating can form a source and a drain of a field effect transistor, silicon dioxide the dielectric and the silicon substrate or another semiconductor the gate.

The invention can be used furthermore in conjunction with organic light diodes (OLED) for electrical circuits, in particular also organic electrical circuits, or with solar cells, in particular also organic solar cells.

Also the layer comprising the semiconducting material can be formed by deposition in a vacuum.

Subsequently, the invention is intended to be explained in more detail by way of example and in comparison to a conventional solution when used for a field effect transistor.

There are thereby shown:

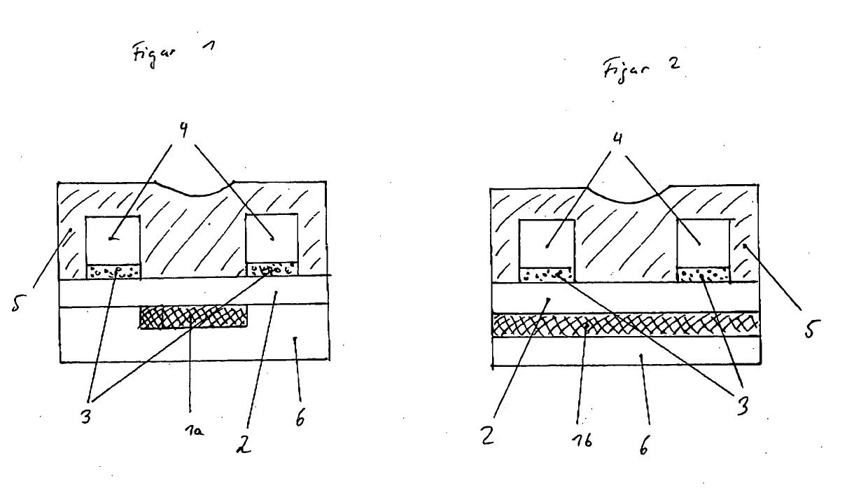

FIG. 1 a first embodiment of a field effect transistor,

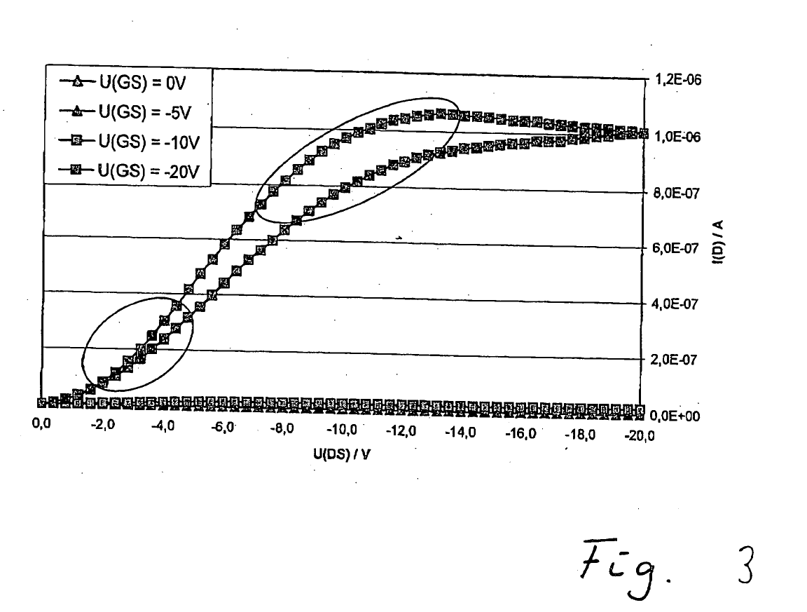

FIG. 2 a second embodiment of a field effect transistor,

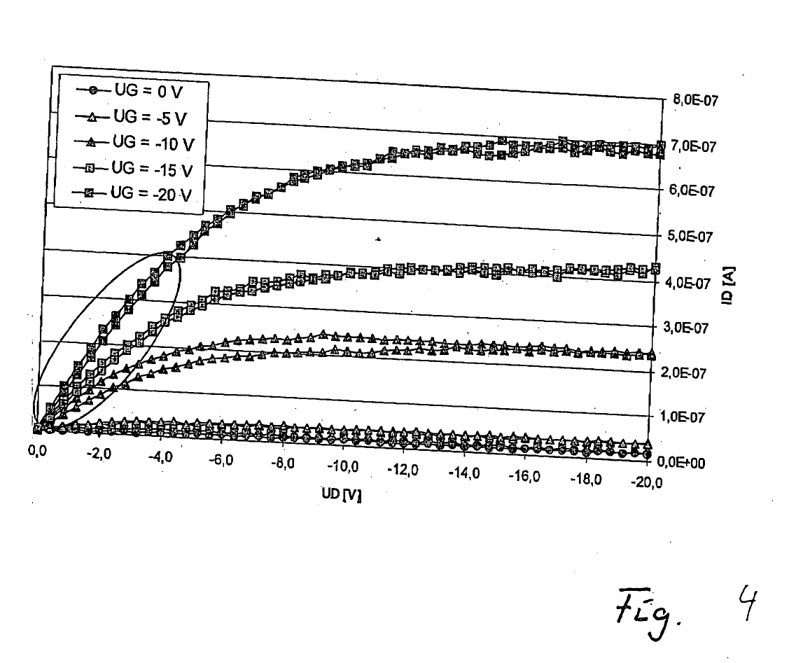

FIG. 3 a diagram of a voltage-current strength course for a field effect transistor configured in the conventional form and

FIG. 4 a diagram of a voltage-current strength course for a field effect transistor configured in the form according to the invention.

FIGS. 1 and 2 show a first and second embodiment of a field effect transistor.

For both embodiments there were applied respectively on a glass carrier 6 with a silicon layer 1a or 1b with high p-doping on which a layer comprising silicon dioxide 2 is formed on the surface, firstly an intermediate layer 3 comprising chromium (state of the art) with a thickness of 5 nm and, according to the invention, an intermediate layer 3 comprising indium-tin oxide with the same thickness onto the surface of the substrate. Then gold was applied thereon as metal by thermal evaporation and structured together with the intermediate layer 3. This structured coating forms electrodes 4 for source and drain of the transistor. The gate is formed by the silicon layer 1a or 1b which is orientated towards the silicon dioxide layer 2. Glass carrier 6 and silicon layer 1a or 1b thereby form the substrate of this layer structure.

On the thus prepared layer structure, a layer 5 which covers at least the electrodes 4 and the surface region situated therebetween and comprises an organic active semiconductor, here pentacene, was deposited.

In the first embodiment, the semiconducting layer 1a forming the gate is structured and formed on the region of the channel defined by the two electrodes in a delimited manner. In the second embodiment, the semiconducting layer 1b forming the gate has been formed over a large area. The advantage of the gate la which is delimited to the channel between the electrodes 4 is that a voltage can be applied specifically to the current-conducting channel and adjacent elements are not affected. Structuring of this type is particularly advantageous for transistors which can be used individually.

The dimensions of a transistor of this type formed by such an interlayer bond can vary greatly according to the application. Preferably, the spacing of the source-drain electrodes 4 is in the range of 1 micrometre to 100 micrometres. The layer thickness of the electrodes is preferably in the range of 10 to 100 nanometres, the layer thickness of the organic semiconductor preferably in the range of 10 to 100 nanometres. The layer thickness of the adhesive layer can likewise vary, layer thicknesses between 1 to 50 nanometres are preferred.

Alternatively, the electrodes 4 and also the intermediate layers 3 can be formed from different materials.

Furthermore, conducting materials can also be used instead of semiconducting materials for the gate 1a, 1b, for example metals or conductive polymers and also conductive metal oxides.

The carrier 6 can comprise a flexible material, for example a PET film, instead of a rigid material, such as for example the mentioned glass.

In both field effect transistors produced with different intermediate layers 3, differences can be established in their use both according to the first and the second embodiment.

In the case of the field effect transistor with the intermediate layer comprising chromium, an initially flat increase in the electrical current (FIG. 3) is significant at small electrical voltages, which can be attributed to the high injection barrier present.

In the case of the field effect transistor (see FIG. 4) configured according to the invention, a significantly greater rise in the electrical current was able to be achieved already at small electrical voltages. At the same time, the hysteresis was also significantly reduced.

The inventive step resides above all in the application of special metal oxides, in particular conductive metal oxides or sulphides. The mentioned materials have the advantage that good adhesion properties accompany an adapted work function, i.e. with an as small as possible injection barrier, and also properties as diffusion barrier against atoms of the applied metals. The substrates according to the invention are characterised in particular in the use as organic field effect transistors, as described in the embodiment, for which the above properties are essential. Due to the small injection barrier, charge carriers can be injected in the semiconducting layer adjacent to the adhesion layer, said charge carriers increasing the current flow between source and drain and hence increasing the effectiveness of the transistor.

1. Interlayer bond to a substrate which, at least in regions on a surface, is provided with a coating of a metal, the substrate or a layer formed on the substrate being electrically non-conducting and, between the coating and the surface of the substrate or the electrically non-conducting layer, an intermediate layer which improves the adhesion of the metal being formed, and a further layer comprising a semiconducting material or materialmixture being formed on the intermediate layer at least in regions, characterised in that the intermediate layer is formed from a metal oxide and/or a sulphide, the metal oxide and/or sulphide for the further layer which comprises a semiconducting material or material mixture having an injection barrier of less than equals 0.6 eV.

2. Interlayer bond according to claim 1, characterised in that the metal oxide and/or sulphide is electrically conducting or semiconducting.

3. Interlayer bond according to claim 1, characterised in that the metal oxide is selected from indium-tin oxide, tin oxide, zinc oxide, zinc-aluminium oxide, antimony oxide or cadmium stannates.

4. Interlayer bond according to claim 1, characterised in that the intermediate layer is formed with cadmium sulphide or zinc sulphide.

5. Interlayer bond according to claim 1, characterised in that the metal oxide is electrically conducting due to doping of at least one element.

6. Interlayer bond according to claim 1, characterised in that there is selected for the coating as metal, gold, silver, aluminium, platinum, palladium, nickel, copper, zinc, iridium or an alloy of one of these metals.

7. Interlayer bond according to claim 1, characterised in that the electrically non-conducting layer is formed directly on the surface of the substrate.

8. Interlayer bond according to claim 1, characterised in that a layer comprising silicon dioxide is formed on the surface of the substrate, the intermediate layer being formed on said silicon dioxide layer.

9. Interlayer bond according to claim 1, characterised in that the substrate is formed from silicon.

10. Interlayer bond according to claim 1, characterised in that the intermediate layer has a thickness of at least 0.1 nm.

11. Interlayer bond according to claim 1, characterised in that the semiconducting material or the material mixture is semiconducting due to doping with at least one element.

12. Interlayer bond according to claim 1, characterised in that the further layer is formed from an organic semiconducting material.

13. Interlayer bond according to claim 1, characterised in that the semiconducting material is pentacene.

14. Method for producing an interlayer bond according to claim 1, characterised in that a surface of the substrate or an electrically non-conducting layer on the substrate is provided with a metal oxide in order to form an intermediate layer and subsequently with a metal layer by means of a vacuum coating method.

15. Method according to claim 14, characterised in that structuring of the formed layers is implemented during or subsequent to the vacuum coating.

16. Use of an interlayer bond according to claim 1 as field effect transistor.

17. Field effect transistor, containing an interlayer bond according to claim 1, the coating with the metal forming two electrodes which can be used as source and drain.

18. Field effect transistor according to claim 17, characterised in that the substrate has a conducting or semiconducting layer which is orientated towards the non-conducting layer and can be used as gate, this layer being formed or structured over a large area and delimited to the region of the channel between the electrodes.
